(19) United States
(12) Patent Application Publication
(10) Pub. No.: US 2023/0208079 A1
(43) Pub. Date: Jun. 29, 2023

(54) COWLING FOR BOARD-TO-BOARD CONNECTORS

(71) Applicant: Apple Inc., Cupertino, CA (US)

(72) Inventors: Noell G. JOHNSON, Gilroy, CA (US); David R. CRAMER, Los Gatos, CA (US); Sina BIGDELI, Saratoga, CA (US); Edward S. HUO, Sunnyvale, CA (US); Jeremy C. FRANKLIN, San Francisco, CA (US); Jason C. SAUERS, Sunnyvale, CA (US)

(21) Appl. No.: 17/992,795

(22) Filed: Nov. 22, 2022

Related U.S. Application Data
(60) Provisional application No. 63/293,584, filed on Dec. 23, 2021.

(51) Int. Cl. H01R 13/639; H01R 12/77; H05K 1/18

(52) U.S. Cl. CPC H01R 13/639; H01R 12/771; H05K 1/18; H01R 12/79

(57) ABSTRACT

Cowlings described herein for board-to-board connectors can provide high stiffness, low weight, and low total cost. Such cowlings can provide ribs with increased thickness for targeted stiffness to resist bowing in a given direction. The layers of the cowlings can include carbon fiber extending in directions parallel to the ribs in some layers and transverse to the ribs in other layers. The layers can be formed together within a mold tool that shapes the fibers into the ribs.

### CROSS-REFERENCE TO RELATED APPLICATION

This application claims the benefit of U.S. Provisional Application No. 63/293,584, entitled “COWLING FOR BOARD-TO-BOARD CONNECTORS,” filed Dec. 23, 2021, the entirety of which is incorporated herein by reference.

### TECHNICAL FIELD

The present description relates generally to electronic devices with interconnected parts, and, more particularly, to cowlings for board-to-board connectors.

### BACKGROUND

Electronic devices, such as portable computing devices, tablets, desktops, and all-in-one computers, cell phones, smart phones, and media phones, storage devices, portable media players, navigation systems, monitors and other devices may include several electronic components such as screens, memories, processors, and the like. These devices may be located on a board, such as printed circuit boards, flex circuits, or other appropriate substrates. Often, these boards are to be connected to each other to provide the desired functions of the electronic device.

### BRIEF DESCRIPTION OF THE DRAWINGS

Certain features of the subject technology are set forth in the appended claims. However, for purpose of explanation, several embodiments of the subject technology are set forth in the following figures.

FIG. 1 illustrates an exploded perspective view of an assembly, according to some embodiments of the subject technology.

FIG. 2 illustrates a perspective view of the assembly of FIG. 1, according to some embodiments of the subject technology.

FIG. 3 illustrates an exploded perspective view of a portion of a cowling, according to some embodiments of the subject technology.

FIG. 4 illustrates a sectional view of layers of a cowling, according to some embodiments of the subject technology.

FIG. 5 illustrates another sectional view of layers of a cowling with outer layers being folded, according to some embodiments of the subject technology.

FIG. 6 illustrates a sectional view of layers of a cowling within a mold, according to some embodiments of the subject technology.

FIG. 7 illustrates a sectional view of a cowling, according to some embodiments of the subject technology.

FIG. 8 illustrates an image of layers of a cowling, according to some embodiments of the subject technology.

### DETAILED DESCRIPTION

The detailed description set forth below is intended as a description of various configurations of the subject technology and is not intended to represent the only configurations in which the subject technology may be practiced. The appended drawings are incorporated herein and constitute a part of the detailed description. The detailed description includes specific details for the purpose of providing a thorough understanding of the subject technology. However, it will be clear and apparent to those skilled in the art that the subject technology is not limited to the specific details set forth herein and may be practiced without these specific details. In some instances, well-known structures and components are shown in block diagram form in order to avoid obscuring the concepts of the subject technology.

An example of a process for securing board-to-board (“B2B”) connectors includes utilizing stainless steel material that is stamped out of thin steel use stainless (“SUS”) sheets in a progressive die. The piece part cost can be relatively low, but the tooling cost can be significant compared to composite tooling costs. The geometric shape of a SUS cowlings is also indicative of the stiffness achieved by using such thin material, but this comes at a mass penalty. The desired attributes of high stiffness, low weight, and low total cost can be achieved with carbon fiber to form the cowling.

A cowling can be provided with ribs that provide greater thickness along regions of the cowling and are oriented in a bending orientation where stiffness is required. To build up the material thickness and make the ribs, layers can be folded onto themselves to build up thickness at various plies of the stack up. Once all layers have been stacked and aligned with the features (e.g., cavities) of a mold, the cowling can be formed with heat and pressure within the mold. After applying heat and pressure, the molded parts can be removed from the mold and trimmed to a final shape. The resulting cowlings can be three times stiffer, one fifth of the weight, and similar overall cost to SUS cowlings.

Typically, SUS cowlings would bow from the pressure of the compressed foams, but carbon fiber cowlings were observed to not bow or bend. The ribs thereof can be oriented with fiber directions in each layer to provided targeted stiffness where desired, which cannot be done with traditional metal parts.

Accordingly, embodiments of the present disclosure may provide cowlings for board-to-board connectors that provide high stiffness, low weight, and low total cost. Such cowlings can provide ribs with increased thickness for targeted stiffness to resist bowing in a given direction. The layers of the cowlings can include carbon fiber extending in directions parallel to the ribs in some layers and transverse to the ribs in other layers. The layers can be formed together within a mold tool that shapes the fibers into the ribs.

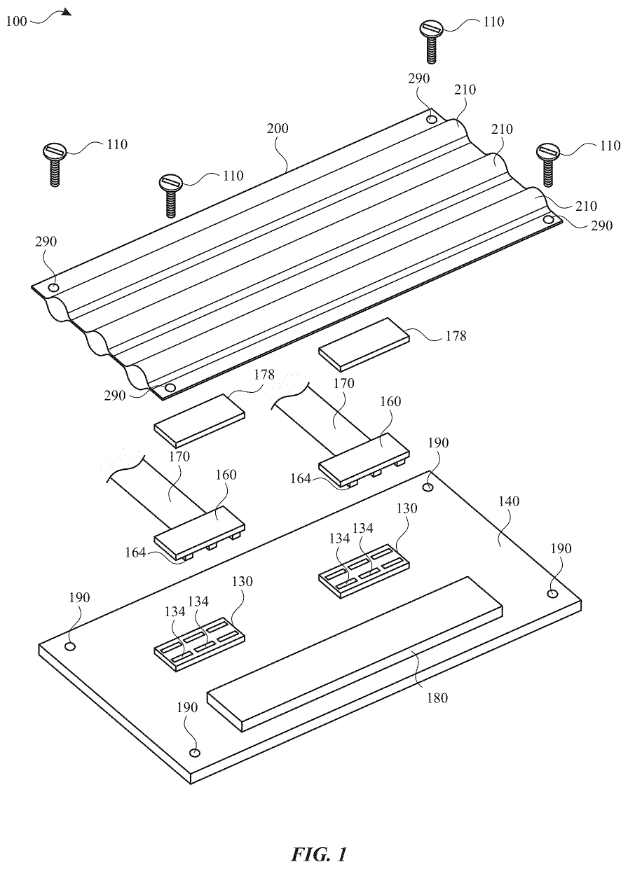

These and other embodiments are discussed below with reference to FIGS. 1-8. However, those skilled in the art will readily appreciate that the detailed description given herein with respect to these Figures is for explanatory purposes only and should not be construed as limiting.

FIG. 1 illustrates an exploded view of a connector assembly according to embodiments of the present disclosure. As shown in FIG. 1, the connector assembly 100 may include a stiffening layer or cowling 200, a plug 160, a flex circuit 170, a receptacle 130, and a printed circuit board 140. The connector assembly can include components of a device or system. Such devices and systems can include, for example, a phone, a tablet computing device, a mobile computing device, a watch, a laptop computing device, a desktop computing device, a mouse, a trackpad, a keyboard, a game controller, a remote control, a digital media player, a wearable device, a stylus, a media player, a control panel, a display, a head-mountable device, a handheld device, a television, and the like.

The board 140 of the connector assembly 100 may be a main logic board or other printed circuit board or appropriate substrate. The board 140 can include one or more circuit components 180 operably connected to the receptacle 130. The receptacle 130 may include contacts 134. The contacts 134 may form electrical connections with traces on the printed circuit board 140. The flex circuit 170 may be connected to plug 160. Traces in the flex circuit 170 may connect to contacts 164 on the plug 160. These contacts 164 may form electrical connections with the contacts 134 on the receptacle 130. In this way, conductors in the flex circuit 170 may connect to traces on the printed circuit board 140 via the contacts 164 on the plug 160 and the contacts 164 on the receptacle 130.

A first stiffening layer or cowling 200 may be provided to secure the plugs 160 to the corresponding receptacles 130. The cowling 200 can secure directly to the board 140 so that the plugs 160 are pressed into and/or against the receptacles 130.

A pliable layer 178 can be placed on each of the plugs 160. The pliable layer 178 can be formed of foam and/or another compressible material. The pliable layer 178 can have retention properties such that a compression force is applied by pliable layer 178 after assembly to keep the plug 160 in place.

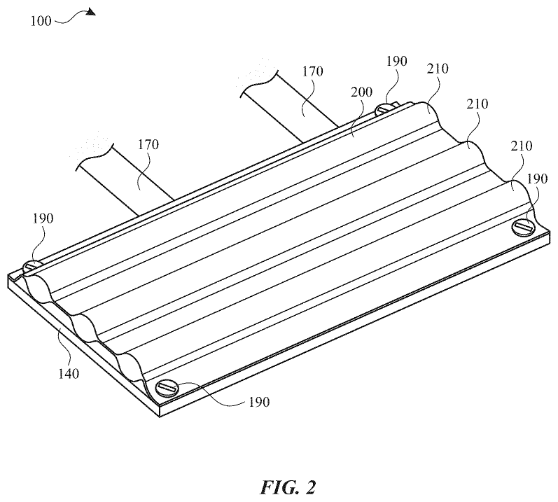

As shown in FIGS. 1 and 2, during assembly, the plugs 160 may be inserted into the receptacles 130. The pliable layer 178 can be placed over the plug 160. The cowling 200 may be placed over the board 140, the pliable layers 178, and the plugs 160. Fasteners 110 can be inserted through slots 290 of the cowling 200 to reach and engage with openings 190 of the board 140. A downward force may be applied to either or both of fasteners 110 and the cowling 200. This force may be applied by hand or by using a tool. This force may press and hold the plugs 160 onto and/or into the receptacles 130.

In these examples, flex circuit 170 is shown as being attached to printed circuit board 140 through connector assembly 100. In other embodiments, more than two boards may be connected using a connector assembly. Moreover, these boards may be possible circuit boards, printed circuit boards, or combinations thereof. For example, two or more flex circuits, or to or printed circuit boards, may be connected together by employing embodiments of the present disclosure.

The connector assembly 100 can further include a pliable layer to be placed on plug 160. The pliable layer can be part of and/or between the cowling and/or the plug 160 and may be formed of foam or another compressible material. The pliable layer can have good retention properties such that a compression force is applied by the pliable layer after assembly to keep the plug 160 engaged with the receptacle 130.

As further shown in FIGS. 1 and 2, the cowling 200 can have a variable thickness. As used herein, the thickness of the cowling is defined by an axis that extends through both the cowling 200 and the board 140, for example an axis that is perpendicular to the board 140. The variation in thickness can be defined by regions having ribs 210 separated by regions having no ribs. At the ribs 210, the cowling 200 can have a greater thickness than at other regions of the cowling 200. The ribs 210 can extend parallel to each other and/or a common axis. For example, the ribs 210 can extend from, to, and/or between ends of the cowling 200 that define a length of the cowling 200. Such a length can be the greatest dimension of the cowling 200. Whereas the cowling 200 can otherwise be susceptible to bowing or bending along its greatest length while securing the plugs 160 to the receptacles 130, the ribs 210 of the cowling can extend along that length to add stiffness that resists bowing along that length.

The cowling can have any number of ribs 210. For example, the cowling 200 can have 1, 2, 3, 4, 5, 6, 7, 8, 9, or more than 9 ribs 210. The ribs can be distributed evenly or unevenly across the cowling 200. The ribs 210 can have the same or different lengths. While the ribs 210 can define thicknesses that are greater than other thicknesses of the cowling 200, the ribs 210 can define the same or different thicknesses compared to each other. The ribs 210 can have widths that are greater than, equal to, or less than the defined thickness at the corresponding region of the cowling 200.

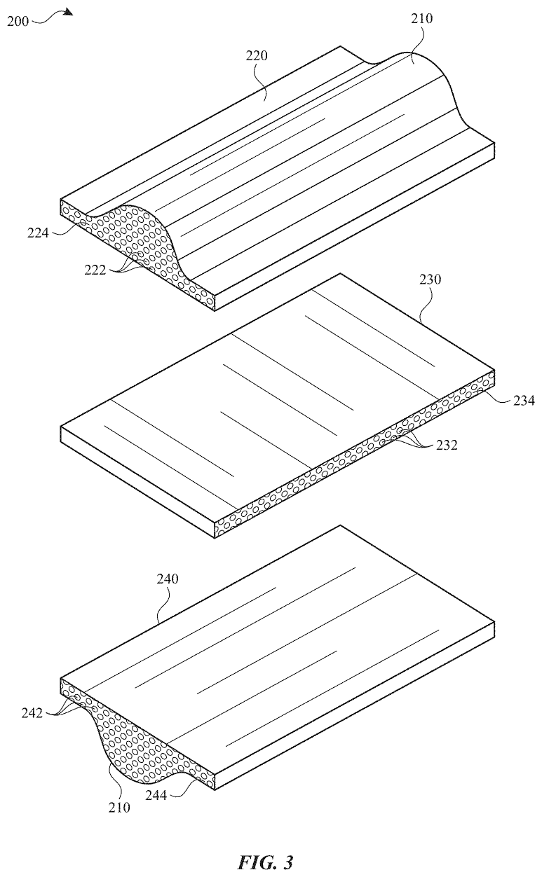

Referring now to FIG. 3, the cowling can be formed by multiple layers stacked on one another. The layers can include an upper layer 220, a middle layer 230, and a lower layer 240. The upper layer 220 can be formed by upper fibers 222 and a resin 224 binding the upper fibers 222 together. The middle layer 230 can be formed by middle fibers 232 and a resin 234 binding the middle fibers 232 together. The lower layer 240 can be formed by lower fibers 242 and a resin 244 binding the lower fibers 242 together. The upper fibers 222, the middle fibers 232, and/or the lower fibers 242 can include carbon fibers. Additionally or alternatively, other fibers are contemplated, such as glass fibers, polymer (e.g., polylactic acid thermoplastic) fibers, organic (cellulose, chitin, flax, etc.) fibers, and the like. The resins can include any binding agent, such as epoxy, vinylester, and polyester resins. The resins can be modified by heat and/or pressure, for example, during molding of the cowling 200.

The upper fibers 222 and the lower fibers 242 can extend in directions that are parallel to each other and/or one or more of the ribs 210 of the cowling 200. For example, the upper fibers 222 and the lower fibers 242 can be shifted over and/or pressed upon each other to form the ribs 210. While ribs 210 are shown in both the upper layer 220 and the lower layer 240, it will be understood that the ribs 210 need not be provided in both layers. The ribs 210 are shown overlapping each other in the upper layer 220 and the lower layer 240 to form an enlarged total thickness of the cowling 200. Additionally or alternatively, it will be understood that the ribs 210 of separate layers can be non-overlapping.

The middle fibers 232 of the middle layer 230 can extend in a direction that is transverse (e.g., perpendicular) to the directions in which the upper fibers 222 and the lower fibers 242 extend and/or the directions in which the ribs 210 extend. The middle layer 230 can provide support to the cowling 200 by supporting the upper fibers 222 and the lower fibers 242. For example, while the upper fibers 222 and the lower fibers 242 and extend in a same direction, they may otherwise be susceptible to separation when bent in certain directions. By providing the middle fibers 232 extending across the upper fibers 222 and the lower fibers 242 and in a position that is between the upper layer 220 and the lower layer 240, the middle fibers 232 of the middle layer 230 help keep the upper fibers 222 and the lower fibers 242 from separating from each other.

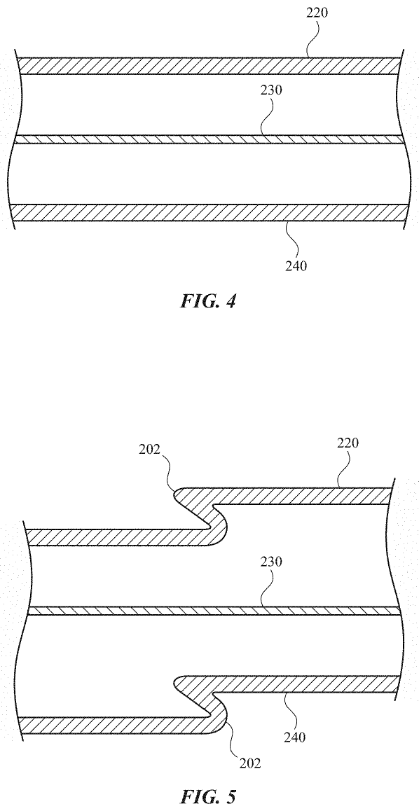

Referring now to FIGS. 4-7, a method is described for forming the cowling with fibers and having variable thickness. As shown in FIG. 4, an upper layer 220, a middle layer 230, and a lower layer 240 can be provided in a stacked arrangement. As described further herein, the upper layer 220 and the lower layer 240 can both include fibers that extend in a common direction, and the middle layer 230 can include fibers that extend in another direction, such as a direction that is transverse to other fibers.

As shown in FIG. 5, the upper layer 220 and the lower layer 240 can each be folded upon itself to form a folded region 202 in which a greater number of fibers are collected together. For example, a pair of bands can be formed to fold portions of each layer on itself. Accordingly, a greater thickness of fibers can be gathered in one folded region 202, and other regions of the upper layer 220 and the lower layer 240 outside the folded region 202 can remain the same. The folding can be performed, for example, with creases along lengths of the fibers, such that the individual fibers of the upper layer 220 and the lower layer 240 need not be folded on themselves. Instead, fibers extending along the same direction can be shifted (e.g., with flexibility provided by a resin or other binder) to provide the folds.

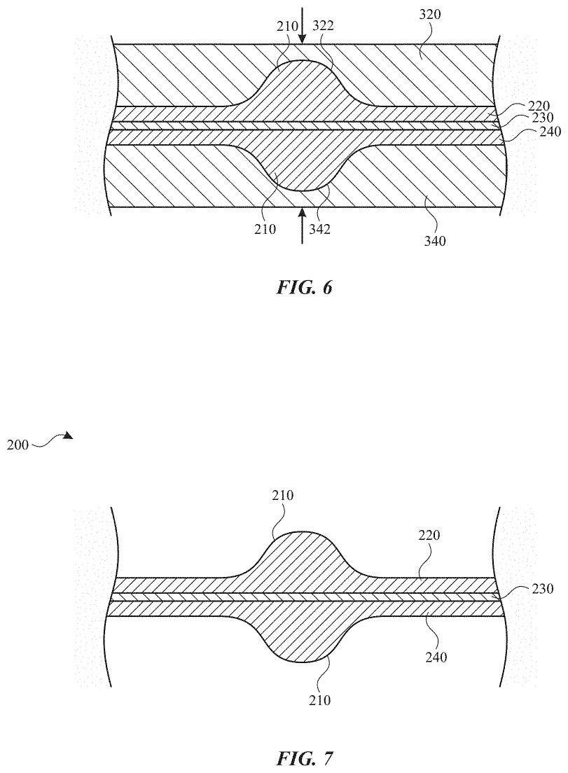

As shown in FIG. 6, the upper layer, the middle layer, and the lower layer can be provided between mold portions of a mold tool. For example, an upper mold portion 320 can be provided adjacent to the upper layer 220, and a lower mold portion 340 can be provided adjacent to the lower layer 240. The upper mold portion 320 can include an upper cavity 322, and/or the lower mold portion 340 can include a lower cavity 342. The folded regions of the layers can be pressed into the corresponding cavities of the mold portions. For example, the folded region of the upper layer 220 can be provided within the upper cavity 322 of the upper mold portion 320, and the folded region of the lower layer 240 can be provided within the lower cavity 342 of the lower mold portion 340. While the initial shapes of the folded regions may not conform to the corresponding cavities, the additional material concentrated at each of the folded regions can readily fill the cavities as heat and pressure are applied. The shapes of the cavities 322 and 342 can correspond to the shapes of the ribs 210 to be formed. For example, the cavities 322 and 342 can extend in the same or parallel directions. By further example, the cavities 322 and 342 can extend parallel to the direction of the fibers of the upper layer 220 and the lower layer 240. As such, the fibers need only shift relative to each other to fit within the cavities, rather than bending along their lengths.

The upper mold portion 320 and the lower mold portion 340 can be pressed against opposing sides of the cowling. Additionally or alternatively, heat can be applied to the layers of the cowling to soften any resin or other binder holding the fibers together. The process can include multiple stages in which heat and/or pressure are applied simultaneously and/or in sequence. For example, an initial amount of heat can be applied to the layers to soften the resin or other binder. Thereafter, pressure can be applied between the upper mold portion 320 and the lower mold portion 340. Pressure can be maintained while the layers are allowed to cool to a target temperature. It will be recognized that the fibers of the upper layer 220 can conform to the cavity 322 and/or other features of the upper mold portion 320, and the fibers of the lower layer 240 can conform to the cavity 342 and/or other features of the lower mold portion 340. Such features can include multiple cavities. In some embodiments, one or more of the cavities of the upper mold portion 320 overlap one or more of the cavities of the lower mold portion 340. In some embodiments, one mold portion provides one or more cavities without the other mold portion providing a corresponding cavity. It will be understood that the fibers of the middle layer 230 need not shift or change substantially or conform to the mold portions. In some embodiments, the middle layer 230 need not come into contact with either one of the mold portions. Where the fibers of the middle layer 230 extend in a direction that is transverse to the direction of the fibers of the upper layer 220 and the lower layer 240, as described herein, the middle layer 230 can remain substantially similar during and throughout the process described herein. As such, the outer peripheral sides of the upper layer 220 and the lower layer 240 can be shaped to conform to the mold portions without substantial changes in the middle layer 230.

As shown in FIG. 7, the mold portions can be removed from the cowling 200. Each of the upper layer 220 and the lower layer 240 can define one or more ribs 210 corresponding to cavities formed in the mold portions applied thereto. Following the process described herein, the ribs and other portions of the cowling 200 can maintain their shape based on the structural integrity of the fibers as well as any resin or other binder bonding the fibers to each other.

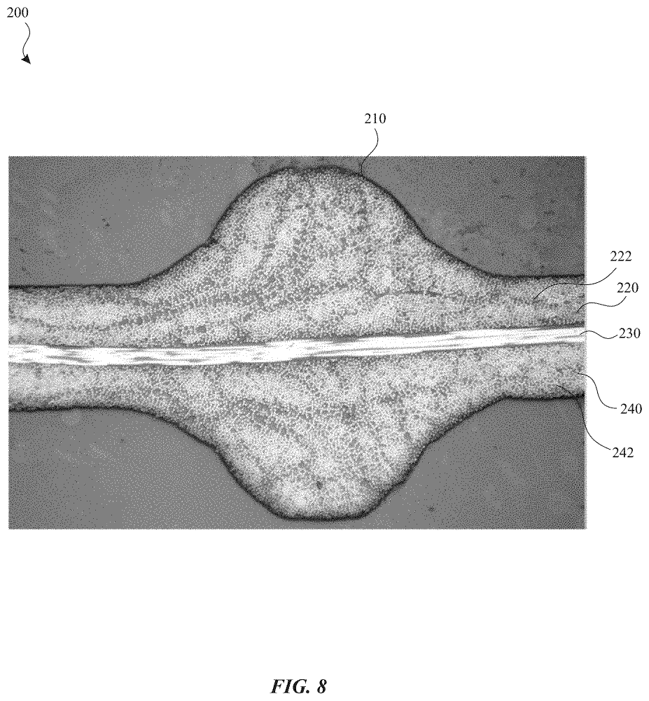

Referring now to FIG. 8, an image of a section of a portion of a cowling is shown. As shown in FIG. 8, the upper fibers 222 and the lower fibers 242 can extend in directions that are parallel to each other (e.g., into the plane of the page) and/or one or more of the ribs 210 of the cowling 200. For example, during the formation process, the upper fibers 222 and the lower fibers 242 can be shifted relative to each other to form the ribs 210. The middle fibers 232 of the middle layer 230 can extend in a direction (e.g., within the plane of the page) that is transverse (e.g., perpendicular) to the directions in which the upper fibers 222 and the lower fibers 242 extend and/or the directions in which the ribs 210 extend. The middle layer 230 can provide support to the cowling 200 by supporting the upper fibers 222 and the lower fibers 242. For example, while the upper fibers 222 and the lower fibers 242 and extend in a same direction, they may otherwise be susceptible to separation when bent in certain directions.

Accordingly, embodiments of the present disclosure may provide cowlings for board-to-board connectors that provide high stiffness, low weight, and low total cost. Such cowlings can provide ribs with increased thickness for targeted stiffness to resist bowing in a given direction. The layers of the cowlings can include carbon fiber extending in directions parallel to the ribs in some layers and transverse to the ribs in other layers. The layers can be formed together within a mold tool that shapes the fibers into the ribs.

Various examples of aspects of the disclosure are described below as clauses for convenience. These are provided as examples, and do not limit the subject technology.

Clause A: a connector assembly comprising: a board having a receptacle; a plug connected to the receptacle of the board; a cowling coupled to the board to secure the plug to the receptacle, the cowling forming ribs extending parallel to each other, the cowling comprising carbon fibers extending in a direction of the ribs.

Clause B: a cowling for coupling to a board, the cowling comprising: an upper layer comprising upper fibers extending in a first direction; a middle layer comprising middle fibers extending in a second direction that is transverse to the first direction; and a lower layer comprising lower fibers extending in a third direction that is parallel to the first direction, wherein the cowling has a varying thickness with ribs that extend parallel to the first direction.

Clause C: a connector assembly comprising: a board having a receptacle; a plug connected to the receptacle of the board; a pliable layer comprising a compressible material; a cowling coupled to the board to press the pliable layer against the plug, the cowling forming ribs extending parallel to each other, the cowling comprising: an upper layer comprising upper fibers extending parallel to the ribs; a middle layer comprising middle fibers extending in a second direction that is transverse to the ribs; and a lower layer comprising lower fibers extending parallel to the ribs.

Clause D: a method comprising: arranging a middle layer between an upper layer and a lower layer, the middle layer comprising fibers that are transverse to fibers of the upper layer and the lower layer; pressing the upper layer, the middle layer, and the lower layer between an upper mold portion and a lower mold portion, each of the upper mold portion and a lower mold portion having recesses extending parallel to the fibers of the upper layer and the lower layer; and applying heat and pressure until the upper layer conforms to the upper mold portion and the lower layer conforms to the lower mold portion.

One or more of the above clauses can include one or more of the features described below. It is noted that any of the following clauses may be combined in any combination with each other, and placed into a respective independent clause, e.g., clause A, B, C, or D.

Clause 1: the carbon fibers are first carbon fibers and the cowling further comprises: second carbon fibers extending transversely to the first carbon fibers; and third carbon fibers extending parallel to the first carbon fibers, the second carbon fibers being between the first carbon fibers and the third carbon fibers.

Clause 2: the ribs comprise: upper ribs formed by the first carbon fibers on a first side of the second carbon fibers; and lower ribs formed by the third carbon fibers on a second side of the second carbon fibers.

Clause 3: each of the upper ribs overlaps a corresponding one of the lower ribs.

Clause 4: the upper ribs and the lower ribs define a maximum thickness of the cowling.

Clause 5: a flex circuit extending from the plug from between the board and the cowling to operably connect the board to an electronic component.

Clause 6: the cowling further comprises a resin bonding the carbon fibers to each other.

Clause 7: fasteners extending through the cowling and engaging the board to secure the cowling against the plug.

Clause 8: the ribs comprise: upper ribs formed by the upper fibers; and lower ribs formed by the lower fibers.

Clause 9: each of the upper ribs overlaps a corresponding one of the lower ribs.

Clause 10: the cowling further comprises a resin bonding the upper fibers, the middle fibers, and the lower fibers.

Clause 11: the resin comprises an epoxy.

Clause 12: the upper fibers, the middle fibers, and the lower fibers comprise carbon fibers.

Clause 13: the cowling comprises openings for receiving fasteners that are configured to engage the board.

Clause 14: the cowling has a length in the first direction that is greater than a width in the second direction.

Clause 15: the compressible material is a foam.

Clause 16: the receptacle is a first receptacle; the plug is a first plug; the pliable layer is a first pliable layer; the board has a second receptacle; the connector assembly further comprises: a second plug connected to the second receptacle of the board; a second pliable layer, the cowling presses the second pliable layer against the second plug.

Clause 17: the upper fibers, the middle fibers, and the lower fibers comprise carbon fibers.

Clause 18: the heat and pressure are applied until a resin bonding the fibers softens.

Clause 19: before the pressing: folding the upper layer onto itself to create an upper folded region of increased thickness, wherein the upper folded region is pressed into an upper cavity of the upper mold portion; and folding the lower layer onto itself to create a lower folded region of increased thickness, wherein the lower folded region is pressed into a lower cavity of the lower mold portion.

Clause 20: the upper cavity of the upper mold portion overlaps the lower cavity of the lower mold portion.

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

As used herein, the phrase “at least one of” preceding a series of items, with the term “and” or “or” to separate any of the items, modifies the list as a whole, rather than each member of the list (i.e., each item). The phrase “at least one of” does not require selection of at least one of each item listed; rather, the phrase allows a meaning that includes at least one of any one of the items, and/or at least one of any combination of the items, and/or at least one of each of the items. By way of example, the phrases “at least one of A, B, and C” or “at least one of A, B, or C” each refer to only A, only B, or only C; any combination of A, B, and C; and/or at least one of each of A, B, and C.

The predicate words “configured to”, “operable to”, and “programmed to” do not imply any particular tangible or intangible modification of a subject, but, rather, are intended to be used interchangeably. In one or more implementations, a processor configured to monitor and control an operation or a component may also mean the processor being programmed to monitor and control the operation or the processor being operable to monitor and control the operation. Likewise, a processor configured to execute code can be construed as a processor programmed to execute code or operable to execute code.

Phrases such as an aspect, the aspect, another aspect, some aspects, one or more aspects, an implementation, the implementation, another implementation, some implementations, one or more implementations, an embodiment, the embodiment, another embodiment, some embodiments, one or more embodiments, a configuration, the configuration, another configuration, some configurations, one or more configurations, the subject technology, the disclosure, the present disclosure, other variations thereof and alike are for convenience and do not imply that a disclosure relating to such phrase(s) is essential to the subject technology or that such disclosure applies to all configurations of the subject technology. A disclosure relating to such phrase(s) may apply to all configurations, or one or more configurations. A disclosure relating to such phrase(s) may provide one or more examples. A phrase such as an aspect or some aspects may refer to one or more aspects and vice versa, and this applies similarly to other foregoing phrases.

The word “exemplary” is used herein to mean “serving as an example, instance, or illustration”. Any embodiment described herein as “exemplary” or as an “example” is not necessarily to be construed as preferred or advantageous over other embodiments. Furthermore, to the extent that the term “include”, “have”, or the like is used in the description or the claims, such term is intended to be inclusive in a manner similar to the term “comprise” as “comprise” is interpreted when employed as a transitional word in a claim.

All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112, sixth paragraph, unless the element is expressly recited using the phrase “means for” or, in the case of a method claim, the element is recited using the phrase “step for”.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language claims, wherein reference to an element in the singular is not intended to mean “one and only one” unless specifically so stated, but rather “one or more”. Unless specifically stated otherwise, the term “some” refers to one or more. Pronouns in the masculine (e.g., his) include the feminine and neuter gender (e.g., her and its) and vice versa. Headings and subheadings, if any, are used for convenience only and do not limit the subject disclosure.

What is claimed is:

1. A connector assembly comprising:
a board having a receptacle;
a plug connected to the receptacle of the board; and
a cowling coupled to the board to secure the plug to the receptacle, the cowling forming ribs extending in a common direction, the cowling comprising carbon fibers extending in the direction of the ribs.

2. The connector assembly of claim 1, wherein the carbon fibers are first carbon fibers and the cowling further comprises:
second carbon fibers extending transversely to the first carbon fibers; and
third carbon fibers extending parallel to the first carbon fibers, the second carbon fibers being between the first carbon fibers and the third carbon fibers.

3. The connector assembly of claim 2, wherein the ribs comprise:
upper ribs formed by the first carbon fibers on a first side of the second carbon fibers; and
lower ribs formed by the third carbon fibers on a second side of the second carbon fibers.

4. The connector assembly of claim 3, wherein each of the upper ribs overlaps a corresponding one of the lower ribs.

5. The connector assembly of claim 4, wherein the upper ribs and the lower ribs define a maximum thickness of the cowling.

6. The connector assembly of claim 1, further comprising a flex circuit extending from the plug from between the board and the cowling to operably connect the board to an electronic component.

7. The connector assembly of claim 1, wherein the cowling further comprises a resin bonding the carbon fibers to each other.

8. The connector assembly of claim 1, further comprising fasteners extending through the cowling and engaging the board to secure the cowling against the plug.

9. A cowling for coupling to a board, the cowling comprising:
an upper layer comprising upper fibers extending in a first direction;
a middle layer comprising middle fibers extending in a second direction that is transverse to the first direction; and
a lower layer comprising lower fibers extending in the first direction,
wherein the cowling has a varying thickness with ribs that extend in the first direction.

10. The cowling of claim 9, wherein the ribs comprise:
upper ribs formed by the upper fibers; and
lower ribs formed by the lower fibers.

11. The cowling of claim 10, wherein each of the upper ribs overlaps a corresponding one of the lower ribs.

12. The cowling of claim 9, wherein the cowling further comprises a resin bonding the upper fibers, the middle fibers, and the lower fibers.

13. The cowling of claim 12, wherein the resin comprises an epoxy.

14. The cowling of claim 9, wherein the upper fibers, the middle fibers, and the lower fibers comprise carbon fibers.

15. The cowling of claim 9, wherein the cowling comprises openings for receiving fasteners that are configured to engage the board.

16. The cowling of claim 9, wherein the cowling has a length in the first direction that is greater than a width in the second direction.

17. A connector assembly comprising:
a board having a receptacle;
a plug connected to the receptacle of the board;
a pliable layer comprising a compressible material;
a cowling coupled to the board to press the pliable layer against the plug, the cowling forming ribs extending parallel to each other, the cowling comprising:
an upper layer comprising upper fibers extending parallel to the ribs;
a middle layer comprising middle fibers extending in a second direction that is transverse to the ribs; and
a lower layer comprising lower fibers extending parallel to the ribs.

18. The connector assembly of claim 17, wherein the compressible material is a foam.

19. The connector assembly of claim 17, wherein:
the receptacle is a first receptacle;
the plug is a first plug;
the pliable layer is a first pliable layer;
the board has a second receptacle;
the connector assembly further comprises:
a second plug connected to the second receptacle of the board;
a second pliable layer,
the cowling presses the second pliable layer against the second plug.

20. The connector assembly of claim 17, wherein the upper fibers, the middle fibers, and the lower fibers comprise carbon fibers.
